(19) United States
(12) Patent Application Publication
(10) Pub. No.: US 2021/0183691 A1
(43) Pub. Date: Jun. 17, 2021

(54) SUBSTRATE FOR AN INTEGRATED RADIOFREQUENCY DEVICE, AND PROCESS FOR MANUFACTURING SAME

(71) Applicant: Soitec, Bernin (FR)

(72) Inventors: Christelle Veytizou, Bernin (FR); Patrick Reynaud, Murianette (FR); Oleg Kononchuk, Theys (FR); Frédéric Allibert, Grenoble (FR)

(21) Appl. No.: 17/257,176

(22) PCT Filed: Jul. 5, 2018
(86) PCT No.: PCT/FR2018/051683

§ 371 Date: Dec. 30, 2020

(51) Int. Cl. H01L 21/762; H01L 21/02; H01L 23/66; H01L 29/16; H01Q 1/22

(52) U.S. Cl. CPC H01L 21/76251; H01L 21/02381; H01Q 1/2283; H01L 29/16; H01L 23/66

(57) ABSTRACT

A substrate for applications in the fields of radiofrequency electronics and microelectronics, comprises: a base substrate; a single carbon layer positioned on and directly in contact with the base substrate, with the carbon layer having a thickness ranging from 1 nm to 5 nm; an insulator layer positioned on the carbon layer; and a device layer positioned on the insulator layer. The disclosure also relates to a process for manufacturing such a substrate

### CROSS-REFERENCE TO RELATED APPLICATIONS

This application is a national phase entry under 35 U.S.C. § 371 of International Patent Application PCT/FR2018/051683, filed Jul. 5, 2018, designating the United States of America and published as International Patent Publication WO 2020/008116 A1 on Jan. 9, 2020.

### TECHNICAL FIELD

The present disclosure relates to a substrate for an integrated radiofrequency device. It also relates to the method for manufacturing such a substrate.

### BACKGROUND

Integrated devices are usually formed on substrates, which are mainly used as supports for the manufacturing thereof. The increase in the degree of integration and expected performance of these devices has led to ever greater coupling between their performances and the characteristics of the substrate on which they are formed. This is more particularly true in the case of RF devices, which process signals, the frequency of which ranges from about 3 kHz to 300 GHz, which are used, in particular, in the field of telecommunications (cellular telephones, Wi-Fi, Bluetooth, etc.).

As an example of device/substrate coupling, the electromagnetic fields from high-frequency signals, which propagate in the devices penetrate into the depth of the substrate and interact with any charge carriers that may be contained therein. This results in a useless consumption of at least a part of the signal energy by coupling loss and possible influences between the components by crosstalk.

According to a second exemplary coupling, the charge carriers of the substrate may generate undesired harmonics, which may interfere with the signals that propagate in the integrated devices and degrade the quality thereof.

Such phenomena can specifically be observed when the substrate used, of the “silicon-on-isolator” type, comprises a buried layer of insulator, between a support and a layer of devices on and in which the integrated devices are formed. The charges trapped in the insulator lead to accumulate charges having complementary signs, which form a conductive plane under such layer of insulator, in the support. In such conductive plane, the mobile charges may strongly interact with the electromagnetic fields generated by the components of the useful layer. A significant drop in the resistivity of the support can thus be observed, in a plane located directly under the buried layer of insulator, even when such support has a highly resistive electrical characteristic.

To prevent or limit such phenomenon, inserting a charge trapping layer, for example, a layer of 1 to 5 microns of polycrystalline silicon between the buried insulator and the support, directly under the insulator, is known. The boundaries of the grains, which form the polycrystalline structure, are then traps for the charge carriers, since the charge carriers can come from the trapping layer itself or from the underlying support. The appearance of the conductive plane under the insulator and the drop in the resistivity of the support are thus avoided. The manufacturing of such type of substrate is, for example, disclosed in the documents FR2860341, FR2933233, FR2953640, US2015115480, U.S. Pat. Nos. 7,268,060 or 6,544,656.

US20150115480 proposes forming the trapping layer in the form of a stack of polycrystalline or amorphous SiGe, Ge or SiC elementary layers, each elementary layer possibly having a thickness of at least about 5 nm and being covered with a layer passivation of some Angstroms.

US2016071959 describes a structure of silicon-on-insulator type comprising on a resistive support a possible thin insulating layer of a few nanometers thick and an amorphous layer of silicon doped with a thickness of between 25 nm and 7 microns. The carbon concentration is between 1 and 10%.

US20130168835 discloses a method of forming a silicon on insulator substrate comprising providing a support substrate; forming a layer of high-resistivity material on the support substrate, the layer of high-resistivity material having a thickness of between 10 and 50 microns and comprising one of amorphous or polycrystalline silicon carbide, polycrystalline or amorphous diamond; forming an insulating layer on the layer of high resistivity material; and assembling a donor wafer to an upper surface of the insulating layer to form the SOI substrate.

This solution of providing a trapping layer based on polycrystalline or amorphous semiconductor material, although quite effective, is relatively expensive, especially when the trapping layer is thick or composed of a stack of elementary layers. In addition, the formation of a thick layer, for example, several microns, may lead to deformation of the wafer on which this layer is formed or to make this layer particularly rough, which makes the manufacturing process particularly difficult. This cost of the solution is difficult to justify for integrated devices requiring low RF performance.

The present disclosure aims at providing a substrate for applications in the fields of radiofrequency electronics and microelectronics, which is simple and not expensive to produce while having a higher level of performances than a substrate of the silicon-on-insulator type, which includes no trapping layer.

### BRIEF SUMMARY

To reach this goal, the object of the present disclosure is to provide a substrate for applications in the fields of radiofrequency electronics and microelectronics comprising:
a base substrate;
a single carbon layer positioned on and directly in contact with the base substrate, with the carbon layer having a thickness strictly ranging from 1 nm to 5 nm;
an insulator layer positioned on the carbon layer;
a layer of devices positioned on the insulator layer.

The carbon layer, which has a very low thickness, forms a trapping layer, which can be very easily, and quite surprisingly, very efficiently produced.

According to other advantageous and non-restrictive characteristics of the present disclosure, taken either separately or in any technically feasible combination:
the base substrate is a single-crystal silicon substrate having a resistivity of less than 100 ohm·cm;
with the base substrate being a single-crystal silicon substrate having a resistivity above 100 or 1,000 ohm·cm;
the carbon layer has a thickness ranging from 1 to 3 nm;
the substrate further comprises a bonding layer positioned between, and in contact with, the carbon layer and the insulator layer;
the bonding layer has a thickness of less than 10 nm;
the bonding layer is made of an amorphous, polycrystalline silicon or made of silicon dioxide;
the insulator layer is made of silicon dioxide;
the layer of devices comprises silicon;
with the layer of devices comprising at least one radiofrequency device.

A method for manufacturing a substrate for applications in the fields of radiofrequency electronics and microelectronics, comprising:
a step of exposing a base substrate to a precursor gas containing carbon to saturate the exposed substrate with carbon species freed from the precursor gas and to form a single carbon layer having a thickness ranging strictly from 1 nm to 5 nm on the base substrate;
a step of assembling the base substrate and the source substrate so as to form an insulator layer between the base substrate and the source substrate;
a step of thinning the source substrate to form a layer of devices.

According to other advantageous and non-restrictive characteristics of the present disclosure, taken either separately or in any technically feasible combination:
the method comprises a step of forming a bonding layer having a thickness of less than 10 nm on, and in contact with, the carbon layer after the exposition step;
the step of forming the bonding layer comprises the deposition of a bonding material and the polishing of the deposited bonding material;
the source substrate is made of silicon and the step of forming the insulator layer comprises the oxidation of the source substrate;
the source substrate comprises radiofrequency devices and the step of forming the insulator layer comprises the deposition of a silicon dioxide layer on the source substrate;
the step of thinning the source substrate comprises a step of progressively reducing a part of the thickness of the source substrate by physical and/or chemical thinning;
the step of thinning the source substrate comprises a first step of forming a brittle plane in the source substrate prior to the step of assembling, and a second step of breaking the source substrate at such brittle plane thereof, after the step of assembling;
the carbon layer has a thickness strictly ranging from 1 to 3 nm.

### BRIEF DESCRIPTION OF THE DRAWINGS

Further characteristics and advantages of the present disclosure will be clear from the detailed description of the present disclosure, made in reference to the appended figures, among which:

FIG. 1 represents a substrate according to a first embodiment of the present disclosure;

FIG. 2 represents a substrate according to a second embodiment of the present disclosure; and

FIG. 3 represents a method for manufacturing a substrate according to the present disclosure.

### DETAILED DESCRIPTION

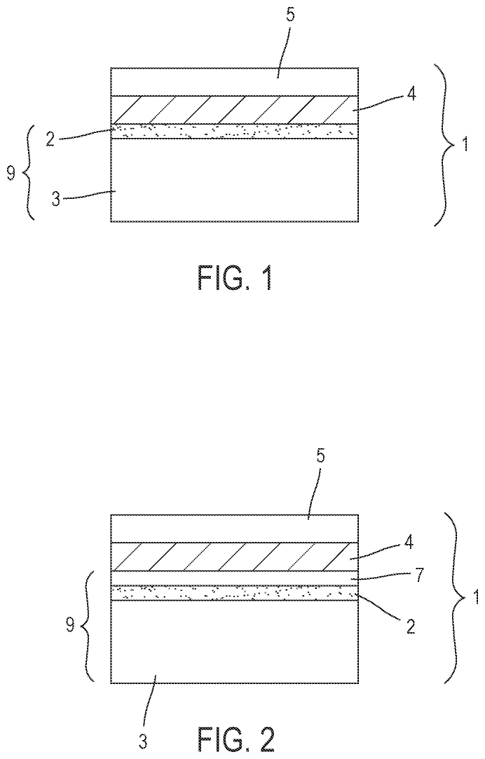

FIG. 1 schematically represents a first embodiment of a substrate 1 for applications in the fields of radiofrequency electronics and microelectronics according to the present disclosure.

The substrate 1 of the first embodiment comprises a base substrate 3, a carbon layer 2 positioned on and directly in contact with the base substrate 3, with the carbon layer having a thickness strictly ranging from 1 nm to 5 nm, and preferentially from 1 to 3 nm; an insulator layer 4 positioned on the carbon layer 2 and a layer of devices 5 positioned on the insulator layer 4. The base substrate 3 provided with the carbon layer 2 forms the support 9 of the substrate 1.

The substrate 1 can have the shape of a circular plate, with standard dimensions, for example, 200 mm or 300 mm, even 450 mm in diameter. This is specifically the case when the substrate, and more particularly the layer of devices 5, carries no device. However, the present disclosure is in no way restricted to these dimensions or this shape.

When the substrate 1 forms the support of a finished or semi-finished radiofrequency device, it will thus have the shape of a block of material having a longitudinal rectangular or square section, the dimensions of which, from a few millimeters to a few centimeters, match the dimensions of the integrated device.

The base substrate 3 has a thickness of several hundreds of microns. Preferentially, the base substrate 3 has a high resistivity, above 100 or 1,000 ohms·cm, and more preferentially above 3,000 ohms·cm. The density of charges, holes or electrons, which might move in the base substrate 3, and thus affect the RF performances of the substrate, is thus limited. But the present disclosure is not limited to a base substrate having such a resistivity, and it also gives advantageous RF performances when the base substrate has a more conventional resistivity, of the order of a few hundreds of ohms·cm, or 100 ohms·cm or less.

For reasons of availability and cost, the base substrate 3 is preferentially made of silicon, and specifically made of single-crystal silicon. This may be, for example, a CZ substrate having a low interstitial oxygen content, which has, as is well known, per se, a resistivity, which may be above 1,000 ohms·cm. The base substrate may also be made of another material: this may be, for example, sapphire, silicon carbide, silicon-germanium, III-V materials, etc. This may also be a more standard single-crystal substrate CZ, the resistivity of which is less than 100 ohms·cm.

The substrate 1 also comprises, on and directly in contact with the base substrate 3, a single carbon layer 2 having a thickness strictly ranging from 1 nm to 5 nm, and preferentially from 1 to 3 nm. The carbon layer 2 aims at limiting the resistivity loss, which is generally observed in the support of a substrate of the silicon-on-isolator type, under the insulator layer, as previously described herein.

Within the scope of the present disclosure, “carbon layer” means a layer made of carbon atoms only. The migration or the diffusion of such atoms in the thickness of the base substrate 3, or the diffusion of the atoms composing the base substrate 3 in the carbon layer 2, on in a few atomic planes, may lead to the forming of a layer, rich in carbon, but possibly containing other species, specifically those the base substrate is made of.

Quite surprisingly, it has been observed that such a carbon layer 2, even with a very low thickness, was very efficient to improve the RF performances of the substrate 1, specifically to limit, or even totally avoid the drop in resistivity of the support 9 at the interface thereof with the insulator layer 4. For example, a carbon layer 2 having a thickness of 3 nm deposited on a base substrate 3 having a resistivity above 1,000 ohms·cm makes it possible to gain 20 dbm in performance when measuring the second harmonic distortion parameter, a distortion from coplanar lines, as compared to a base substrate having no carbon layer 2. Such a characterization measurement is disclosed in the document entitled “White paper—RF SOI Characterization,” dated March 2016, published by the SOITEC company, of Bernin, France.

This results from the fact that such a layer comprises a significant density of defects forming traps for the charge carriers. Such density of defects is by several orders of magnitude above what could be obtained with a crystalline or amorphous layer of a semi-conductive material having the same thickness, made of silicon, silicon-germanium, silicon carbide or any other material.

Because of the extreme thinness of a few nanometers, the carbon layer 2 is also simple and cheap to produce, as compared to the trapping layers, several microns thick, of the prior art, which are made of polycrystalline and amorphous material.

As shown in FIG. 1, the substrate 1 comprises an insulator layer 4 directly on the carbon layer 2. The substrate also comprises a layer of devices 5, on and in contact with the insulator layer 4. The characteristics of these two layers are not essential to the present disclosure. For example, the insulator layer 4 can be made of, or comprise, silicon dioxide or silicon nitride. It may also be a stacking of such materials. The thickness of the insulator layer 4 can range from 10 nm to 10 microns. The layer of devices 5 is usually made of single-crystal silicon, but it could be made of any other material, whether semi-conductive or not, according to the nature of the RF device intended to be formed therein. Thus, to form an acoustic wave device, the layer of devices 5 can be made of an insulator such as lithium tantalate or lithium niobate. The thickness of the layer of devices can range from 10 nm to 10 microns. The devices can be formed in such layer of devices 5 when it is borne by the support 9, but, as will be disclosed hereunder, the devices can also be formed in this layer before it is added on the support 9. Obviously, the device layer 5 is continuous, i.e., covers most of the main face of the substrate 1, so that this substrate can accommodate a high density of components.

FIG. 2 schematically shows a second embodiment of the substrate 1 according to the present disclosure.

The substrate 1 of the second embodiment comprises the same base substrate 3, the same carbon layer 2, the same insulator layer 4 and the same layer of devices 5 as in the substrate 1 of the first embodiment. To be concise, the descriptions thereof will not be repeated, and the same comments made in relation with the description of the substrate 1 of the first embodiment will also apply to the substrate 1 of the second embodiment.

As can easily be seen in FIG. 2, the substrate 1 also comprises a bonding layer 7 positioned between, and in contact with, the carbon layer 2 and the insulator layer 4.

The purpose of the bonding layer 7 is to facilitate the manufacture of the substrate as will be disclosed in further detail below. The bonding layer 7 can be made of amorphous, polycrystalline silicon or of silicon dioxide, but other materials can also be considered. The possible influence thereof on the level of RF performances of the substrate is secondary. However, care shall be taken that it does not affect such performances. For this purpose, the thickness and the conductivity thereof will be limited as much as possible. Preferably, the bonding layer 7 has a thickness of less than 10 nm. When made of a semi-conductive material, the bonding layer 7 has a dopant concentration of less than 10 E14 atoms per cubic centimeter. It may be rich in carbon so as to be resistive.

Whatever the embodiment selected, the substrate 1 contains no other layer but the single carbon layer 2 and, if need be, the bonding layer 7, between the base substrate 3 and the insulator layer 4. The level of RF performances, and specifically the resistivity of the support 9 in a plane located under the insulator layer 4, is essentially provided by the carbon layer 2.

An advantage of the substrate 1 of the present disclosure is that the carbon layer 2 is not sensitive to the heat treatment, which the substrate might be exposed to. It will unlikely lose its charge trapping effects by recrystallization as is the case for polycrystalline or amorphous trapping layers of the state of the art. The substrate 1 can thus be exposed, in the course of its manufacturing or in the course of forming the RF devices in and on the layer of devices 5, to a high temperature, for example, up to 1,200° C. when the base substrate 3 and the layer of devices 5 are made of silicon.

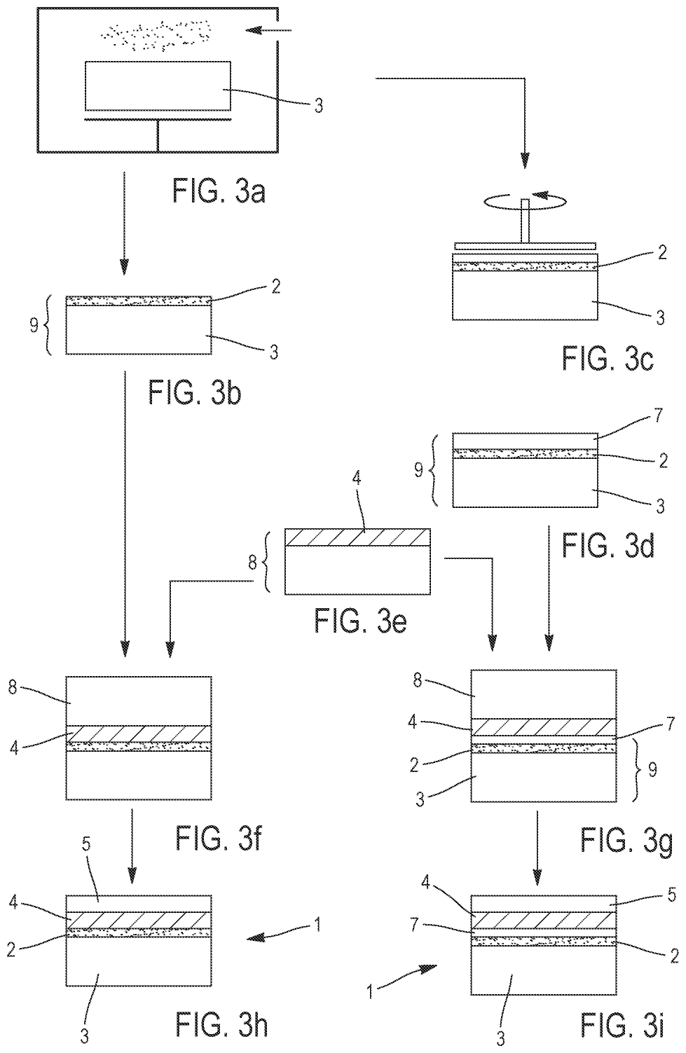

An exemplary manufacturing method according to the present disclosure is now described with reference to FIG. 3.

Generally speaking, the manufacturing of the substrate 1 comprises the preparation of the base substrate 3 to provide it with the carbon layer 2 (and possibly with the bonding layer 7) to form the support 9, and the transfer of a layer of devices 5 onto the support 9.

The preparation of the base substrate 3 is particularly simple and achievable with standard equipment industry. The base substrate 3 is provided in a conventional deposition chamber or even in a chamber of an annealing furnace in which a gas can be circulated to control its atmosphere. As is well known per se, the base substrate 3 may be prepared, prior to deposition, to be exposed to a carbon-containing precursor gas, for example, to remove a native oxide layer from its surface.

As is schematically represented in FIG. 3a, the chamber is then flowed with a precursor gas containing carbon, for example, C₃H₈, at a temperature on the order of 1000° C., and preferably greater than 1000° C. for exposing the base substrate 3 to this precursor gas and forming the carbon layer 2. The precursor gas may comprise or be composed, for example, of methane (CH₄), ethane (C₂H₆), propane (C₃H₈), acetylene (C₂H₂), ethylene (C₂H₄), etc. The carbon species released by the precursor gas under the effect of temperature bind to the atomic species forming the exposed surface of the base substrate 3. This reaction can be interrupted naturally when this surface is saturated with carbon, leading to the formation of a carbon layer 2 having a thickness of a few atomic planes, strictly between 1 and 5 nm and even strictly between 1 and 3 nm. The duration of this exposure is sufficient so that the carbon layer covers the exposed surface of the base substrate 3 and the thickness is strictly between 1 and 5 nm, or between 1 and 3 nm. The exposure time is of the order of a few minutes, ideally and in a non-limiting manner between 2 and 10 minutes, and at the end of this period, the chamber can be purged of the precursor gas containing carbon or its interrupted flow. As previously discussed, it is possible for carbon atoms to diffuse in some atomic planes in the thickness of the base substrate 3. Similarly, atomic species of the base substrate may also migrate into the deposited carbon layer. In any case, and whatever the exact nature of the layer that is formed, only carbon atoms are deposited to form the carbon layer 2.

At the end of this step, the support 9, shown in FIG. 3b, is obtained. This support is intended to be assembled, for example, by molecular adhesion to a source substrate 8. For this purpose, it should be noted that the exposed surface of the carbon layer 2 does not require any particular smoothing treatment, in particular, by polishing, since, as a matter of fact, it has, directly after being formed, a roughness, smaller than 5 Angstroms RMS, low enough to enable the assembling thereof to the source substrate 8. It is also to be noted that the particularly thin carbon layer has a very uniform thickness over the entire surface of the support 9. Such a uniform thickness and such a low level of roughness cannot be obtained with thicker layers, especially those exceeding 1 or 10 microns. The support 9 is not likely to deform when it undergoes a heat treatment, by the effect of the stresses that can develop in the thick layers when they have different thermal expansion coefficients.

As the carbon layer 2 has a different nature from that of the source substrate 8, it may have a surface requiring a preparation, which will also be different from that of the source substrate 8. Thus to simplify the manufacturing method, and according to an alternative solution to this method, the present disclosure can provide to form, on the carbon layer 2, a bonding layer 7, the surface of which can be prepared as the source substrate is. It may be, for example, cleaning with chemical substances having identical or similar compositions, dispensed by the same equipment. Such approach contributes to the low cost of manufacturing of the substrate 1.

When, according to an alternative solution to the manufacturing method, forming a bonding layer 7 on the carbon layer 2 is desired, a second precursor gas can be introduced into the chamber as a substitute for or as a complement of the precursor rich in carbon for a determined time to deposit a thickness of bonding material. Care shall be taken to deposit a low thickness so as to limit the substrate 1 manufacturing time and cost as much as possible. It can, for example, range from a few dozens of nanometers to a few hundreds of nanometers. The second precursor gas can be made of SiH₄ to form a bonding layer made of polycrystalline or amorphous silicon.

Such an “in-situ” embodiment is particularly advantageous, since it makes it possible to combine, in a single step and on a single piece of equipment, the step of forming the carbon layer 2 and the deposition of the bonding material the bonding layer 7 is made of. But, alternately, the deposition of the bonding material can be executed on another piece of equipment, for example, a piece of equipment making it possible to deposit a silicon oxide material. Whatever the nature of the bonding material and the equipment with which such material is deposited on the carbon layer 2, care shall be taken to limit the thickness to a few hundreds of nanometers as mentioned above. The thickness of the bonding material is then prepared, for example, by mechanical-chemical polishing, so as to make the surface thereof smooth enough, of less than 5 Angstroms RMS, to enable the assembling thereof to the source substrate 8. This is shown in FIG. 3c. Such a step of smoothing leads to thinning the thickness of the bonding material, to provide the bonding layer 7, the thickness of which preferably does not exceed 10 nm, so as not to substantially affect the RF performances of the substrate. Upon completion of this step, and as shown in FIG. 3d, a support 9 comprising the bonding layer 7 is obtained, the thickness of which does not exceed 10 nm, positioned directly on the carbon layer 2, itself directly positioned on the base substrate 3.

Whether the selected support 9 comprises a bonding layer or not, the transfer of the layer of devices 5 is executed by assembling the face of a source substrate 8 to the support 9. The source substrate may include RF devices or it may be formed by a block of material with no device.

Advantageously, such assembling corresponds to a bonding by molecular adhesion of the surfaces of the source substrate 8 and of the support 9 in contact with each other.

The transfer may include, prior to the step of assembling, a step of forming a thickness of insulator on the support 9 and/or on the source substrate 8. After assembling, the thickness or thicknesses form(s) the insulator layer 4. When the insulator is formed by deposition, such deposition may be followed by a step of polishing. Such an insulator can comprise, for example, silicon oxide or silicon nitride. When the source substrate is made of silicon and has no device, the step of forming the insulator layer may include the oxidation thereof. FIG. 3e shows the source substrate 8 provided with the insulator layer. Assembling the source substrate 8 with the support 9 leads to placing the insulator layer 4 between the support 9 and the source substrate 8, as shown in FIG. 3f, when the support 9 comprises no bonding layer, and shown in FIG. 3g, when the support 9 comprises a bonding layer 7.

To reinforce such assembly, the structure of FIGS. 3f and 3g may be exposed to a thermal annealing. The step of annealing can be executed, in the method, directly after the step of assembling and/or after the step of thinning, which is described below. As mentioned above, such an annealing may include the exposure of the structures to a high temperature, without taking the risk of affecting the RF performances of the substrate obtained when the manufacturing method is completed.

After the step of assembling, the donor substrate is thinned to form the layer of devices 5.

The step of thinning can be executed by the progressive reduction of a part of the thickness of the source substrate through a physical and/or chemical thinning.

Alternately, this can be a fracture at the brittle plane previously formed in the source substrate prior to the assembling thereof with the support, according to the principles of the Smart Cut™ technology.

Steps of finishing the layer of devices 5, as well as a step of polishing, a step of heat treatment under a reducing or neutral atmosphere (in a vertical, horizontal, oven or in fast heat treatment equipment), a sacrificial oxidation can follow the step of thinning.

After such a thinning process and any needed finishing processes, a substrate 1 according to the present disclosure is obtained, as shown in FIG. 3h, when the support 9 comprises no bonding layer, and in FIG. 3i when the support 9 comprises a bonding layer 7.

When the source substrate 8 is a simple semiconductor substrate, i.e., it does not comprise any integrated device, a substrate of the semiconductor-on-isolator type is thus obtained, wherein the layer of devices 5 is a layer of blank semiconductors. The substrate can then be used to form integrated devices, and specifically radiofrequency integrated circuits.

When the source substrate 8 has previously been processed to form integrated devices at the surface thereof, when such method is completed, a layer of devices 5, which comprises such devices is obtained.

Of course, the present disclosure is not limited to the described embodiments and alternative solutions can be used without leaving the scope of the invention as defined in the claims.

1. A substrate for applications in the fields of radiofrequency electronics and microelectronics, comprising:
a base substrate;
a carbon layer positioned on and directly in contact with the base substrate, with the carbon layer having a thickness in a range extending from 1 nm to 5 nm;
an insulator layer positioned on the carbon layer; and
a device layer positioned on the insulator layer.

2. The substrate of claim 1, wherein the base substrate is a single-crystal silicon substrate having a resistivity of less than 100 ohm·cm.

3. The substrate of claim 1, wherein the base substrate is a single-crystal silicon substrate having a resistivity above 100 or 1,000 ohm·cm.

4. The substrate of claim 1, wherein the carbon layer has a thickness in a range extending from 1 to 3 nm.

5. The substrate of claim 1, further comprising a bonding layer positioned between, and in contact with, the carbon layer and the insulator layer.

6. The substrate of claim 5, wherein the bonding layer has a thickness of less than 10 nm.

7. The substrate of claim 5, wherein the bonding layer comprises a material selected from among amorphous silicon, polycrystalline silicon, and silicon dioxide.

8. The substrate of claim 1, wherein the insulator layer comprises silicon dioxide.

9. The substrate of claim 1, wherein the layer of devices comprises silicon.

10. A substrate according to one of the preceding claims, wherein the device layer comprises at least one radiofrequency device.

11. A method for manufacturing a substrate for applications in the fields of radiofrequency electronics and microelectronics, comprising:
exposing a base substrate to a precursor gas containing carbon to saturate a surface of the exposed substrate with carbon species freed from the precursor gas and to form a single carbon layer having a thickness in a range extending from 1 nm to 5 nm on the base substrate;
forming an insulator material on the carbon layer and/or on a source substrate, the insulator material having a thickness;
assembling the base substrate and the source substrate so as to form an insulator layer between the base substrate and the source substrate; and
thinning the source substrate to form a device layer.

12. The method of claim 11, further comprising forming a bonding layer having a thickness of less than 10_nm on, and in contact with, the carbon layer after the exposing of the base substrate to the precursor gas.

13. The method of claim 12, wherein forming the bonding layer comprises depositing a bonding material and polishing of the deposited bonding material.

14. The method of claim 11, wherein the source substrate comprises silicon, and forming the insulator material comprises oxidizing the source substrate.

15. The method of claim 11, wherein the source substrate comprises radiofrequency devices, and wherein forming the insulator material comprises depositing a silicon dioxide layer on the source substrate.

16. The method of claim 11, wherein thinning the source substrate comprises progressively reducing a thickness of the source substrate by physical and/or chemical thinning.

17. The method of claim 11, wherein thinning the source substrate comprises a first step of forming a brittle plane in the source substrate prior to the assembling of the base substrate and the source substrate, and a second step of breaking the source substrate at the brittle plane after assembling of the base substrate and the source substrate.

18. The method of claim 11, wherein the carbon layer has a thickness in a range extending from 1 nm to 3 nm.
